(19) United States
(12) Patent Application Publication
(10) Pub. No.: US 2011/0253524 A1
(43) Pub. Date: Oct. 20, 2011

(54) Aluminum-scandium alloy film applied to vehicle lamps and manufacturing method thereof

(76) Inventors: Jing-Chie Lin, Zhongli City (TW); Hsueh-Lung Liao, Zhongli City (TW); Jian-Jhong Shen, Zhongli City (TW); Sheng-Long Lee, Zhongli City (TW)

(21) Appl. No.: 13/169,376

(22) Filed: Jun. 27, 2011

Related U.S. Application Data
(62) Division of application No. 12/632,888, filed on Dec. 8, 2009.

(30) Foreign Application Priority Data
May 11, 2009 (TW) 098115602

(51) Int. Cl. C23C 14/35; C23C 14/14

(52) U.S. Cl. 204/192.15

(57) ABSTRACT

An aluminum-scandium (Al—Sc) alloy film applied to vehicle lamps and a manufacturing method thereof are revealed. The Al—Sc alloy film contains a trace of scandium so that both temperature for grain refinement and temperature for recrystallization of the film are increased. This results in a fine and smooth surface of the Al—Sc alloy film and the Al—Sc alloy film has better optical reflectivity. Moreover, the Al—Sc alloy film has high recrystallization temperature and high adhesion strength. After high temperature annealing treatment, the Al—Sc alloy film still has higher corrosion resistance.

The current application is a divisional application of, and claims a priority to U.S. 12/632,888 filed on Dec. 8, 2009.

### BACKGROUND OF THE INVENTION

1. Field of Invention

The present invention relates to an aluminum-scandium (Al—Sc) alloy film and a manufacturing method thereof, especially to an Al—Sc alloy film applied to vehicle lamps and a manufacturing method thereof.

2. Description of Related Art

Due to excellent optical reflectivity of metal films, they are applied to coat on reflector of vehicle lamps, especially films made from pure aluminum or aluminum alloy. Under high temperature, hillocks usually appear on the aluminum film surface. Thus reflectivity of the reflector is decreased.

The aluminum alloy film has features of low electric resistance, high adhesion strength, economic value and better graphing and ability to be treated by dry etching. Yet similar to the pure aluminum film, the aluminum alloy film also tends to have hillocks under high temperature that cause reduction of the reflectivity.

There are various factors that result in hillocks on surfaces of the pure aluminum film or aluminum alloy film in a high temperature environment. E. Iwamura et al. pointed that microstructure of the hillock is a polycrystalline structure and the morphology relates to grain size of the film. When there are many small grains in the film and hence more grain boundaries, a larger hillock with lower density is generated. On the other hand, the hillock generated is with smaller size and higher density due to the large grain size and columnar crystal orientation.

In order to solve the problem of hillocks (protrusions) on the surface of the pure aluminum film and aluminum alloy film under high temperature, alloy elements are added into the pure aluminum film for increasing yield strength of the film so that the film is more durable to compressive thermal stress occurred during annealing and the generation of the hillock is further suppressed. The addition of alloy elements leads to two reinforcements of the film in the as-deposited condition. The first is grain boundary strengthening. As demonstrated by the Hall-Petch equation, there is then an inverse relationship between grain size and yield strength. The other is solid-solution strengthening. The alloying element diffuses into the aluminum matrix, forming a solid solution that impedes dislocation movement. Thus the strength of the film is improved. During annealing processes of the aluminum film added with alloying element, grain growth is retarded due to grain boundary segregation of part of the alloying element in the aluminum matrix. Even after high temperature annealing, the grain size of the film is far more smaller than that of the pure aluminum film. Thus the film strength is not significantly reduced due to annealing. Therefore, the formation of hillock on the film is suppressed.

In 1990, H. S. Hu et al. found that after the addition of rare earth metal elements such as samarium (Sm) to Al films, 90% Sm atoms is dissolved into the aluminum matrix under the as-deposited condition. During high temperature annealing, part of Al₃Sm is segregated at the boundaries. The formation of the segregation not only reduces the resistivity but also retards the grain growth. And the hillock growth is further suppressed.

As to the report of Y. K. Lee et al. in 1991, 0.7 weight percent (wt %) Y (yttrium) is added to the Al film. After annealing treatment, the grain growth is suppressed due to part of Al₃Y segregated at boundaries. Even the annealing temperature is as high as 500° C. (degrees Celsius), the grain size of the Al—Y film is only half of that of the pure Al film, about 302 nm. Thus the film strength is not considerably reduced due to annealing treatment and the hillock growth is further inhibited.

In 1996, S. Takayama pointed that the addition of rare earth metal elements such as 2.0-7.0 at. % Lanthanum (La) or praseodymium (Pr) to Al films leads to great reduction of grain size of Al—La or Al—Pr films, only about 50% of the grain size of the pure aluminum film. During high temperature annealing at 350° C., most of Al₃La and Al₃Pr segregate at boundaries so that the grain growth is suppressed and the hillock growth on the film surface is further inhibited.

In 1997, T. Onish et al. pointed that the amount of neodymium (Nd) added into the Al film affects density of the hillock on the film surface. After the Al film being treated by annealing at constant temperature 400° C. for 1 hour, the density of the hillock on the film surface reduces along with the increase of the amount of Nd when the amount of Nd is within 6.0 at. %. If the amount of Nd ranges from 2.0 to 6.0 at. %, the hillock formation on the film is completely suppressed. Once the amount of Nd is over 6.0 at. %, the hillock growth is not inhibited. On the contrary, the density of the hillocks on the film is increased.

As to the Al—Sc alloy film applied to vehicle lamps of the present invention, there is slightly hillock growth on the film surface under high temperature conditions. The Al—Sc alloy film contains traces amounts of scandium so as to have a flat and smooth surface. Thus the Al—Sc alloy film has better optical reflectivity.

### SUMMARY OF THE INVENTION

Therefore it is a primary object of the present invention is to provide an aluminum-scandium (Al—Sc) alloy film applied to vehicle lamps and a manufacturing method thereof. The Al—Sc alloy film contains trace amounts of scandium so that both temperature for grain refinement and temperature for recrystallization are increased and this leads to a flat and smooth surface of the Al—Sc alloy film. Therefore, the Al—Sc alloy film is with better optical reflectivity.

It is another object of the present invention is to provide an Al—Sc alloy film applied to vehicle lamps and a manufacturing method thereof. The Al—Sc alloy film has high recrystallization temperature and high adhesion strength. Moreover, after being treated by high temperature annealing, the Al—Sc alloy film is still with higher corrosion resistance.

In order to achieve the above objects, an Al—Sc alloy film applied to vehicle lamps and a manufacturing method thereof are provided. The Al—Sc alloy film is used in a vehicle lamp. The Al—Sc alloy film includes a substrate and an Al—Sc alloy layer coated on the substrate. The amount of Sc in the Al—Sc alloy film ranges from 0.1 to 1.7 weight percent.

The manufacturing method of the Al—Sc alloy film according to the present invention includes the following steps. Firstly, set an Al—Sc alloy target and a substrate into a chamber. Then pump the air out of the chamber so that a vacuum is created in the chamber. At last, introduce a argon gas into the chamber and control DC (direct current) power in a planar magnetron so as to coat an Al—Sc alloy layer on the substrate.

### BRIEF DESCRIPTION OF THE DRAWINGS

The structure and the technical means adopted by the present invention to achieve the above and other objects can be best understood by referring to the following detailed description of the preferred embodiments and the accompanying drawings, wherein

FIG. 1 is a flow chart of an embodiment according to the present invention;

FIG. 2 is a bar chart showing relationship between adhesion strength and films made from different materials according to the present invention;

FIG. 3 shows relationship between optical reflectivity and different films being treated by various ways;

FIG. 4 shows relationship between corrosion current and annealing time of different embodiments of the present invention.

### DETAILED DESCRIPTION OF THE PREFERRED EMBODIMENT

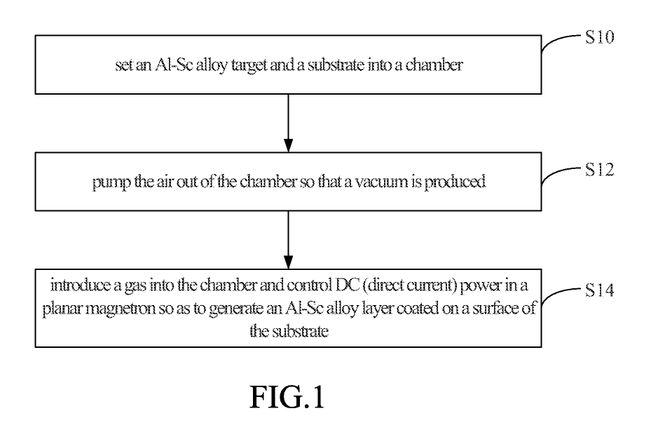

Refer to FIG. 1, a flow chart of an embodiment of the present invention is revealed. The Al—Sc alloy film manufactured by this embodiment is applied to vehicle lamps. The Al—Sc alloy film includes a substrate and an Al—Sc alloy layer coated on the substrate. The amount of Sc in the Al—Sc alloy film ranges from 0.1 to 1.7 weight percent. The substrate is made from glass or plastic or aluminum. The trace amounts of scandium in the Al—Sc alloy film result in increases of temperature for grain refinement and temperature for recrystallization. Thus the Al—Sc alloy film has a flat and smooth surface. Therefore, the Al—Sc alloy film has better optical reflectivity. Moreover, the Al—Sc alloy film has high recrystallization temperature and high adhesion strength. Furthermore, after being treated by high temperature annealing, the Al—Sc alloy film is still with higher corrosion resistance.

In this embodiment, a manufacturing method of the Al—Sc alloy film is to coat the Al—Sc alloy film onto the vehicle lamps by evaporation or sputtering. At first, take the step S10, set an Al—Sc alloy target and a substrate into a chamber. The Al—Sc alloy target is formed by melting and blending of pure aluminum and aluminum scandium (Al—Sc) alloy. The Al—Sc alloy contains 0.1% to 1.7% by weight of scandium and the substrate can be glass or plastic or aluminum. Then run the step S12, pump the air out of the chamber so that a vacuum is produced in the chamber and pressure in the chamber ranges from 1×10⁻⁵ torr to 9×10⁻⁵ torr.

Next take the step S14, introduce an argon gas into the chamber and control DC (direct current) power in a planar magnetron so as to generate an Al—Sc alloy layer coated on a surface of the substrate. In this embodiment, the gas is argon and the pressure of the gas introduced ranges from 1×10⁻³ torr to 3×10⁻³ torr. The DC power powered the planar magnetron ranges from 90 KW to 100 KW.

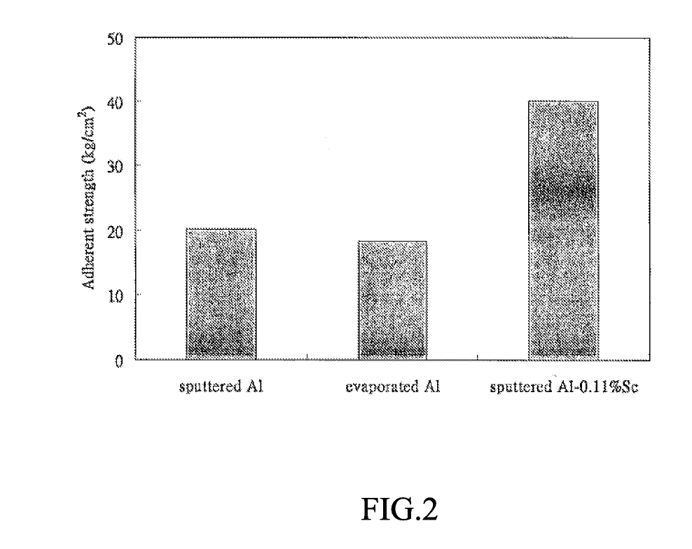

Refer to FIG. 2, a bar chart demonstrating comparison of the adhesion strength among different films is shown. The adhesion strength of the aluminum film and that of the Al—Sc alloy film containing 0.11% by weight of scandium are compared. In the figure, the bars respectively representing adhesion strength of the evaporated aluminum film, adhesion strength of the sputtered aluminum film, and adhesion strength of the sputtered Al—Sc alloy film are getting longer from left to right. The chart shows that the Al—Sc alloy film is with optimal adhesion strength.

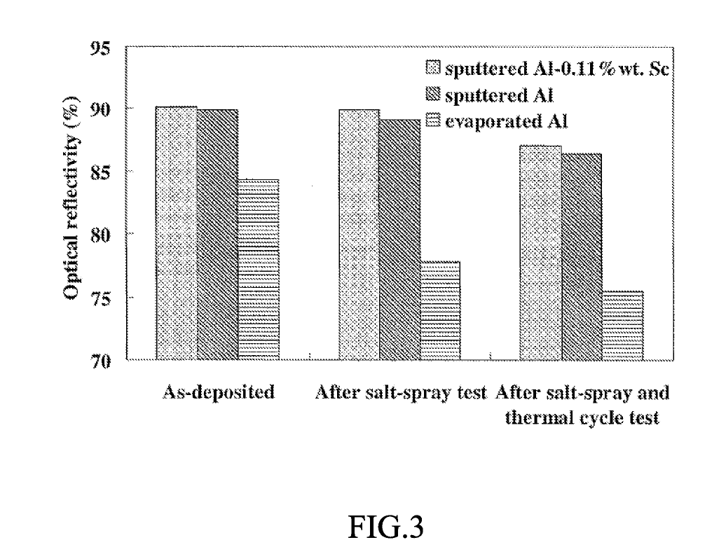

Refer to FIG. 3, a bar chart showing relationship between films treated by various tests and the optical reflectivity is revealed. The Al—Sc alloy film containing 0.11 weight percent (0.11 wt %) of scandium and an aluminum film are tested by salt spray test or are exposure to salt spray and thermal cycling. Before the test, the optical reflectivity of the Al—Sc alloy film is as high as 90.1%. After the salt spray test and the thermal cycling test, the optical reflectivity is reduced into 87%. As to the aluminum film being evaporated, the optical reflectivity before the test is 84.3%. After the salt spray test and the thermal cycling test, the optical reflectivity is dropped to 75.5% significantly.

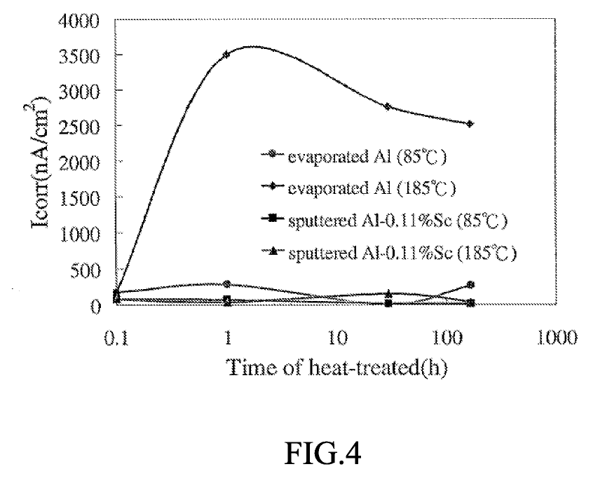

Refer to FIG. 4, the figure shows relationship between corrosion current and the annealing time of various films. As shown in the figure, the Al—Sc alloy film containing 0.11 weight percent (0.11 wt %) of scandium and an aluminum film, both are annealed at 85 degrees Celsius and 185 degrees Celsius respectively. The corrosion current of the Al—Sc alloy film being annealed at 85 degrees Celsius and 185 degrees Celsius are both quite low. This represents that the Al—Sc alloy film has excellent corrosion resistance.

In summary, the present invention provides an Al—Sc alloy film applied to vehicle lamps and a manufacturing method thereof. The Al—Sc alloy film mainly applied to vehicle lamps. The trace amounts of Sc in the Al—Sc alloy film results in the increase of grain refinement temperature and recrystallization temperature. Thus the surface of the Al—Sc alloy film is flat and smooth and the Al—Sc alloy film has better optical reflectivity. Furthermore, the Al—Sc alloy film has high recrystallization temperature and high adhesion strength. After high temperature annealing treatment, the Al—Sc alloy film still has higher corrosion resistance.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalents.

What is claimed is:

1. A manufacturing method of a Al—Sc alloy film applied to vehicle lamps comprising the steps of:
setting an Al—Sc alloy target and a substrate into a chamber,
pumping the air out of the cavity so as to create a vacuum in the chamber, and
coating an Al—Sc alloy layer on the substrate by introducing an argon gas into the cavity and controlling DC (direct current) power in a planar magnetron.

2. The method as claimed in claim 1, wherein the substrate is made from plastic or aluminum.

3. The method as claimed in claim 1, wherein the substrate is made from glass.

4. The method as claimed in claim 1, wherein the Al—Sc alloy target is formed by melting and blending of pure aluminum and aluminum scandium alloy.

5. The method as claimed in claim 4, wherein the aluminum scandium alloy contains 0.1% to 1.7% by weight of scandium.

6. The method as claimed in claim 1, wherein vacuum pressure in the chamber ranges from 1×10⁻⁵ torr to 9×10⁻⁵ torr.

7. The method as claimed in claim 1, wherein the gas is argon.

8. The method as claimed in claim 1, wherein pressure of the argon gas introduced ranges from 1×10⁻³ torr to 3×10⁻³ torr.

9. The method as claimed in claim 1, wherein the DC power in the planar magnetron ranges from 90 KW to 100 KW.
